(19) United States
(12) Patent Application Publication
(10) Pub. No.: US 2020/0027722 A1
(43) Pub. Date: Jan. 23, 2020

(54) LASER ANNEALING DEVICE, LASER ANNEALING METHOD, AND MASK

(71) Applicant: SAKAI DISPLAY PRODUCTS CORPORATION, Sakai-shi, Osaka (JP)

(72) Inventor: HIDETOSHI NAKAGAWA, Sakai-shi, Osaka (JP)

(21) Appl. No.: 16/476,725

(22) PCT Filed: Jan. 24, 2017
(86) PCT No.: PCT/JP2017/002399

§ 371 Date: Oct. 10, 2019

(51) Int. Cl. H01L 21/02; H01L 21/67

(52) U.S. Cl. CPC H01L 21/0268; H01L 29/78672; H01L 21/67115

(57) ABSTRACT

Provided are a laser annealing device, laser annealing method, and mask which make it possible to reduce display blurriness at a mask-joining boundary. The laser annealing device is equipped with a mask in which a plurality of opening blocks, which include a plurality of openings arranged in the column direction parallel to the scanning direction, are arranged in the row direction which is perpendicular to the scanning direction. The laser annealing device moves the mask and/or substrate in a direction parallel to the scanning direction, and each time the mask and/or substrate move to a prescribed position in the direction perpendicular to the scanning direction, performs processing for irradiating a plurality of prescribed substrate regions with a laser beam through the plurality of openings. Furthermore, at least one pair comprising adjacent two opening blocks is provided in a manner such that the position of the openings in a first opening block which is one block among the pair and the position of the openings in a second opening block which is the other block among the pair are offset in the direction parallel to the scanning direction.

### TECHNICAL FIELD

The present invention relates to a laser annealing device, a laser annealing method, and a mask.

### BACKGROUND ART

A thin-film-transistor (TFT) liquid-crystal display has a structure in which, with a TFT substrate and a color filter substrate having red (R), green (G), and blue (B) colors bonded together with a desired gap, liquid crystals are injected into the gap between the TFT substrate and the color filter substrate. Controlling light transmittance of liquid crystal molecules pixel by pixel enables the TFT liquid-crystal display to display an image.

The TFT substrate is provided with data lines and scanning lines arranged in a grid pattern in longitudinal and lateral directions, and includes a plurality of pixels formed at intersections of the data lines and the scanning lines. Each of the pixels is composed of a TFT, a pixel electrode, a counter electrode, and a liquid-crystal layer existing between the pixel electrode and the counter electrode. The TFT substrate is also provided with a driver circuit formed around the periphery of a display area composed of the plurality of pixels. The driver circuit is composed of TFTs, and drives the data lines and the scanning lines.

Examples of TFTs developed include an amorphous silicon (noncrystalline, a-Si) TFT with a silicon semiconductor, and a low-temperature poly-silicon TFT with a semiconductor layer of poly-silicon (polycrystal, p-Si). The a-Si TFT has high resistance and a small leak current. The p-Si TFT is also remarkably larger in electron mobility than the a-Si TFT.

It is possible to convert an amorphous silicon layer into a polysilicon layer by causing laser beams to strike the amorphous silicon layer to perform annealing of the amorphous silicon layer. For example, there is a laser annealing device that divides a laser beam emitted from a laser light source into collimated beams through lenses, and causes the collimated beams divided to strike a substrate through a mask with openings and a micro-lens array. In this type of laser annealing device, a mask has a plurality of openings arranged in a matrix pattern in a scanning direction and a direction perpendicular to the scanning direction. Whenever the mask or a substrate is moved by a pixel pitch in the scanning direction, the laser annealing device emits a laser beam. This enables the laser beams to strike desired places of the substrate (spots struck by the beams) predetermined times equal to the number of opening blocks arranged in the scanning direction every one cycle of scan. When one cycle of scan is completed, the mask or substrate is returned to the start position for a next cycle of scan, and the next cycle of scan is performed (see Patent Literature 1).

### CITATION LIST

### Patent Literature

Patent Literature 1: Japanese Patent No. 5470519

### SUMMARY OF INVENTION

### Technical Problem

FIG. 17 is a schematic illustration depicting a configuration of a mask employed for a conventional laser annealing device, and a relationship between a cycle of scan and a mask position. As illustrated in FIG. 17, the mask has a plurality of openings arranged in a matrix pattern in a scanning direction and a direction perpendicular to the scanning direction. In the example of FIG. 17, ten openings are aligned in the scanning direction. A desired number of opening blocks, each of which is composed of ten openings in a direction parallel to the scanning direction, are arranged side by side in the direction perpendicular to the scanning direction. For example, the left mask illustrates the mask's position at a first scan, and the right mask illustrates the mask's position at a second san that is the next scan. The mask's position may be a scan's start position per cycle, or a position shifted by a voluntary distance from the scan's start position in the scanning direction.

At the first scan, deviation of spots struck by laser beams and deviation of emission timing are constant at each opening in the mask (e.g., each opening arranged in the direction perpendicular to the scanning direction). Similarly, at the second scan, deviation of spots struck by laser beams and deviation of emission timing are constant at each opening in the mask (e.g., each of openings aligned in the direction perpendicular to the scanning direction). The deviation of spots struck by laser beams and the deviation of emission timing at the first san differ from the deviation of spots struck by laser beams and the deviation of emission timing at the second scan. That is, the emission conditions (e.g., spots struck and emission timing) in the mask are constant. However, adjacent masks at the first and second scans are affected by the deviation of spots struck and the deviation of emission timing by the number of openings aligned in the scanning direction (i.e., emission frequency).

FIG. 18 is a schematic illustration depicting a state of a display area corresponding to the spots struck by laser beams from the conventional laser annealing device. In FIG. 18, the left rectangle illustrates a display area corresponding to the spots struck at the first scan, and the right rectangle illustrates a display area corresponding to the spots struck at the second scan. As illustrated in FIG. 18, the influence of the deviation of spots struck and the deviation of emission timing occurs between the first scan and the second scan. This causes difference in characteristics of a semiconductor layer, and generates uneven display around a boundary between the scans. The boundary is hereinafter also referred to as a mask joint boundary.

The present invention has been made in view of such circumstances, and an object thereof is to provide a laser annealing device and a laser annealing method, capable of reducing uneven display around a mask joint boundary, and a mask employed for the laser annealing device.

### Solution to Problem

A laser annealing device according to an embodiment of the present invention includes a mask including opening blocks arranged side by side in a row direction perpendicular to a scanning direction. Each of the opening blocks includes openings aligned in a column direction parallel to the scanning direction. The laser annealing device performs a process of moving at least one of the mask and a substrate in a direction parallel to the scanning direction, and emitting a laser beam to predetermined areas on the substrate through the openings whenever at least one of the mask and the substrate is moved to a predetermined position in a direction perpendicular to the scanning direction. The opening blocks include at least one set of adjacent two opening blocks. A position of an opening of a first opening block that is one opening block of the set, and a position of an opening of a second opening block that is the other opening block of the set are shifted relative to each other in the direction parallel to the scanning direction.

A laser annealing method according to an embodiment of the present invention is a laser annealing method using the laser annealing device according to the embodiment of the present invention. The laser annealing method includes moving, by the laser annealing device, at least one of the substrate and the mask in the direction parallel to the scanning direction to emit the laser beam on the substrate through the openings. The moving at least one of the substrate and the mask in the direction parallel to the scanning direction to emit the laser beam on the substrate through the openings is performed whenever at least one of the mask and the substrate is moved to the predetermined position in the direction perpendicular to the scanning direction.

A mask according to an embodiment of the present invention is a mask including opening blocks arranged side by side in a row direction perpendicular to a scanning direction. Each of the opening blocks includes openings aligned in a column direction parallel to the scanning direction. The opening blocks include at least one set of adjacent two opening blocks. A position of an opening of a first opening block that is one opening block of the set, and a position of an opening of a second opening block that is the other opening block of the set are shifted relative to each other in the direction parallel to the scanning direction.

### Advantageous Effects of Invention

The present invention enables reduction in uneven display around a mask joint boundary.

### BRIEF DESCRIPTION OF DRAWINGS

FIG. 1 is a schematic illustration depicting a configuration example of a laser annealing device according to the present embodiment.

FIG. 2 is a schematic plan view depicting a configuration example of a mask according to the present embodiment.

FIG. 3 is a schematic illustration depicting a positional relationship between each opening and a corresponding micro-lens according to the present embodiment.

FIG. 4A is a schematic illustration depicting an example of a substrate scanned by the laser annealing device according to the present embodiment.

FIG. 4B is a schematic illustration depicting an example of the substrate scanned by the laser annealing device according to the present embodiment.

FIG. 4C is a schematic illustration depicting an example of the substrate scanned by the laser annealing device according to the present embodiment.

FIG. 4D is a schematic illustration depicting an example of the substrate scanned by the laser annealing device according to the present embodiment.

FIG. 5 is a schematic illustration depicting a configuration example of openings of the mask according to the present embodiment.

FIG. 6 is a schematic illustration depicting a state of a display area corresponding to spots struck by laser beams from the laser annealing device according to the present embodiment.

FIG. 7 is a schematic illustration depicting a first arrangement example of the openings of the mask according to the present embodiment.

FIG. 8 is a schematic illustration depicting an example of a state in which uneven display of a display area containing a mask joint boundaries brought about by the mask according to the present embodiment is reduced.

FIG. 9 is a schematic illustration depicting a second arrangement example of the openings of the mask according to the present embodiment.

FIG. 10 is a schematic illustration depicting a third arrangement example of the openings of the mask according to the present embodiment.

FIG. 11 is a schematic illustration depicting a fourth arrangement example of the openings of the mask according to the present embodiment.

FIG. 12 is a schematic illustration depicting a fifth arrangement example of the openings of the mask according to the present embodiment.

FIG. 13 is a schematic illustration depicting a sixth arrangement example of the openings of the mask according to the present embodiment.

FIG. 14 is a schematic illustration depicting a seventh arrangement example of the openings of the mask according to the present embodiment.

FIG. 15 is a schematic illustration depicting an eighth arrangement example of the openings of the mask according to the present embodiment.

FIG. 16 is a flow chart depicting an example of a laser annealing method using the laser annealing device according to the present embodiment.

FIG. 17 is a schematic illustration depicting a configuration of a mask employed by a conventional laser annealing device, and a positional relationship between scan cycles and mask positions.

FIG. 18 is a schematic illustration depicting a state of a display area corresponding to spots struck by laser beams from the conventional laser annealing device.

### DESCRIPTION OF EMBODIMENTS

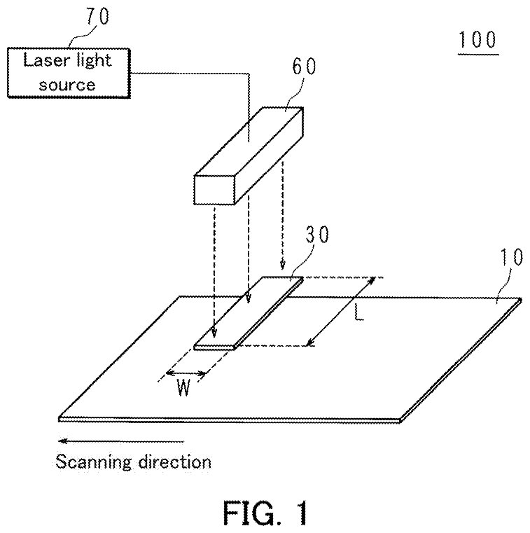

The present embodiment of the present invention will hereinafter be described with reference to the drawings. FIG. 1 is a schematic illustration depicting a configuration example of a laser annealing device 100 according to the present embodiment. The laser annealing device 100 according to the present embodiment includes a laser light source 70, an optical system 60, a mask (a light-shielding plate) 30, and the like. The laser light source 70 emits a laser beam. The optical system 60 includes lenses for dividing the laser beam emitted from the laser light source 70 into collimated beams. The mask 30 has openings and micro-lenses, to be described later, which are arranged in an array.

This configuration causes the collimated beams divided by the optical system 60 to strike partially predetermined areas on a substrate 10 through the openings and the micro-lenses provided for the mask 30. An unillustrated driver mechanism carries the substrate 10 at a constant speed. The laser light source 70 emits the laser beam at time intervals—whenever spots to be struck by the collimated beams on the substrate 10 reach positions corresponding to the openings. Note that the laser annealing device 100 may be configured to move the mask 30 with the substrate 10 fixed in place of the configuration in which the substrate 10 is moved. An example in which the substrate 10 is moved will hereinafter be described.

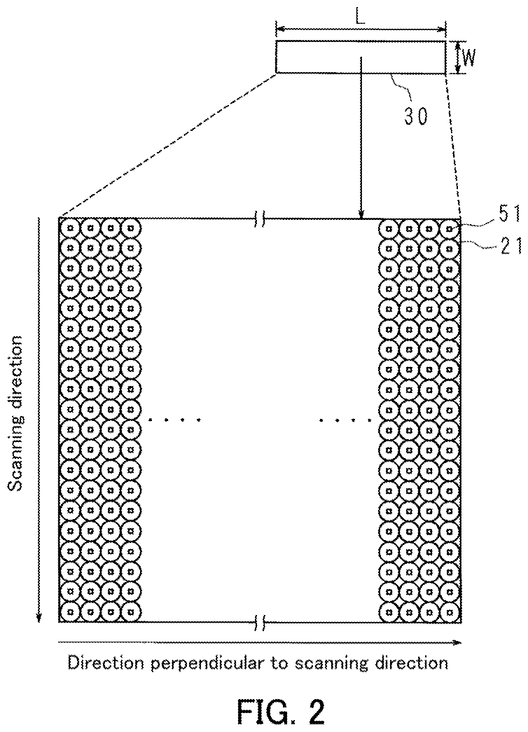

FIG. 2 is a schematic plan view depicting a configuration example of the mask 30 according to the present embodiment. It is assumed that a dimension of the mask 30 in a direction parallel to a scanning direction thereof (also called a column direction) is “W”, and a dimension of the mask 30 in a direction perpendicular to the scanning direction (also called a row direction) is “L”. The mask 30 is provided with micro-lenses 21 arranged at regular intervals in an array—in a matrix having the direction parallel to the scanning direction and the direction perpendicular to the scanning direction.

For example, the dimension W of the mask 30 in the column direction may be about 5 mm, and the dimension L in the row direction may be about 37 mm, but those dimensions are not limited thereto. Predetermined number (in the example of FIG. 2, twenty) of micro-lenses 21 are arranged at regular intervals in the direction parallel to the scanning direction (in the column direction). Each of the micro-lenses 21 is arranged with respect to a corresponding opening 51. Note that the example of FIG. 2 illustrates that in order to depict a positional relationship between the micro-lenses 21 and the openings 51, the openings 51 are arranged so as to correspond to all the micro-lenses 21. However, in the present embodiment, one or more openings 51 are not arranged at one or more positions corresponding to part of the micro-lenses 21.

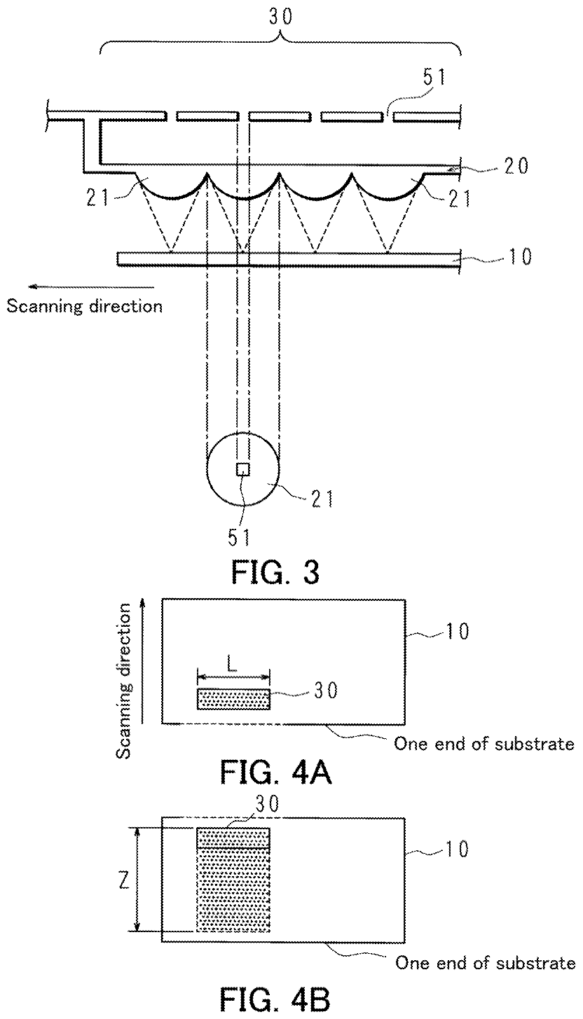

FIG. 3 is a schematic illustration depicting a positional relationship between the openings 51 and the micro-lenses 21 according to the present embodiment. FIG. 3 depicts the positional relationship between the openings 51 and the micro-lenses 21 in plan view, and also depicts a position of an opening 51 in plan view with the position of a micro-lens 21 corresponding to the opening 51 defined as a reference. As illustrated in FIG. 3, the mask 30 has the openings 51 and the micro-lenses (lenses) 21. Note that the micro-lenses 21 are formed on a transparent substrate 20 so as to correspond to the respective openings 51, and the transparent substrate 20 and the mask 30 are configured integrally. The openings 51 are also arranged so that respective centers of the micro-lenses 21 that are circular in plan view substantially match respective centers of the openings 51 that are rectangular in plan view. The mask 30 is also arranged apart by an appropriate length from an incidence plane of the micro-lenses 21. A maximum size of each micro-lens 21 (a diameter of the circle in plan view) may be, for example 150 μm to 400 μm, but are not limited thereto. The micro-lenses 21 are also called a micro-lens array.

The collimated beams divided by the optical system 60 travel toward the openings 51 of the mask 30, and then respective laser beams passing through the openings 51 are focused by the micro-lenses 21. The laser beams focused partially strike predetermined areas on the substrate 10 with the beams corresponding to the respective openings 51 (i.e., micro-lenses 21).

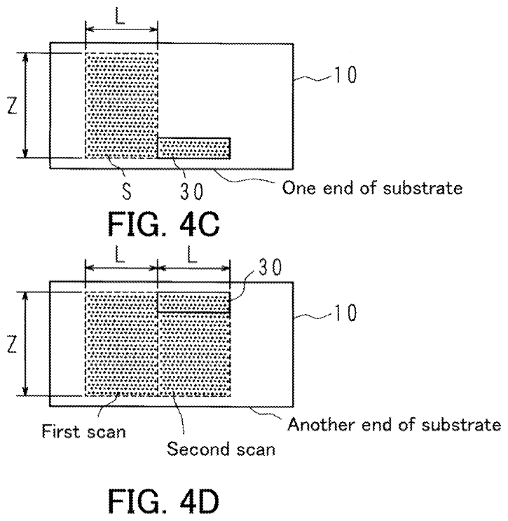

Each of FIGS. 4A, 4B, 4C, and 4D is a schematic illustration depicting a scan example of the substrate 10 by the laser annealing device 100 according to the present embodiment. FIG. 4A illustrates a state in which the mask 30 is set to a predetermined position (e.g., a first scan start position) before the substrate 10 starts to move in the scanning direction. The laser annealing device 100 moves the substrate 10 at a constant speed in the scanning direction from a state illustrated in FIG. 4A. The laser light source 70 emits a laser beam at time intervals-whenever spots to be struck by the collimated beams on the substrate 10 reach respective positions corresponding to the openings 51. In the case where the mask includes a predetermined number of openings 51 aligned in the direction parallel to the scanning direction, the laser beams are to strike the same places on the substrate 10 (the spots to be struck) predetermined times.

FIG. 4B illustrates a state in which the substrate 10 is moved at a constant speed to a final position in the scanning direction (by a distance Z). As a result, the first scan ends.

FIG. 4C illustrates a state in which the substrate 10 is moved and the mask 30 is set to a second scan start position. The first scan makes a state in which predetermined areas within a range of the spots S, to be struck by the collimated beams, on the substrate 10 are struck by the laser beams predetermined times.

FIG. 4D illustrates a state in which the substrate 10 is moved at a constant speed to the final position in the scanning direction (by the distance Z). As a result, the second scan ends. As illustrated in FIG. 4D, the area scanned by the first scan and the area scanned by the second scan are joined with a boundary in the direction parallel to the scanning direction existing therebetween. Note that the figures illustrate only the scans performed two times for the sake of convenience, but in practice, many more scans are performed. The figures also illustrate that the size of the substrate 10 is similar to the size of the mask 30, but in practice, the size of the substrate 10 is much larger than the size of the mask 30.

The mask 30 according to the present embodiment will next be described in detail.

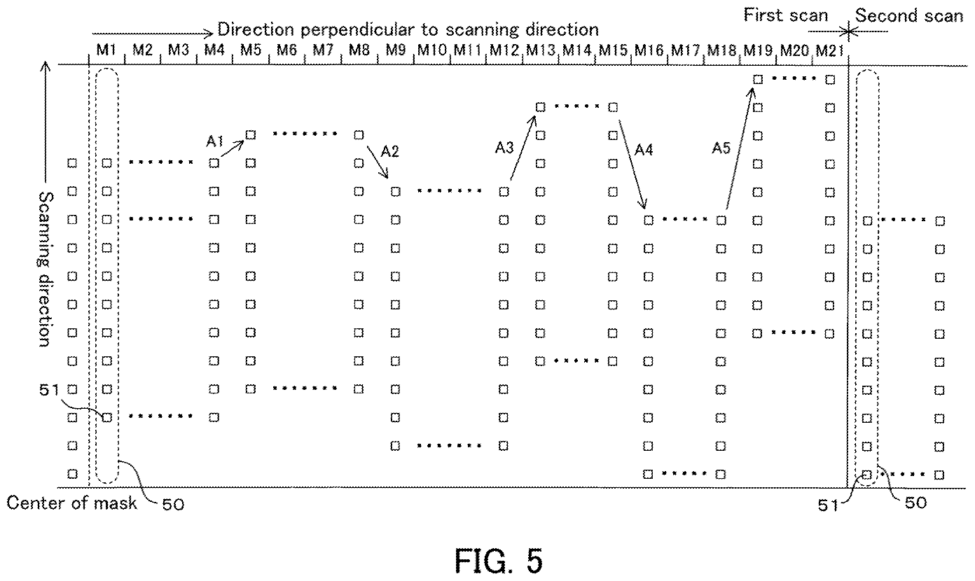

FIG. 5 is a schematic illustration depicting a configuration example of the openings 51 of the mask 30 according to the present embodiment. In the description below, the mask 30 is divided at a center thereof in the direction perpendicular to the scanning direction, and illustrated from the center to one end of the mask 30 (e.g., a right half). Openings 51 arranged in the right half of the mask 30 and openings 51 arranged in the left half thereof may be line symmetrical with a symmetry axis that is a center line segment of the mask 30 parallel to the scanning direction, or point symmetric with a middle point of the symmetry axis.

Note that FIG. 5 illustrates a predetermined position of the mask 30 at the first scan (examples of the predetermined position may include a scan start position, and a position shifted by a predetermined distance from the scan start position), and a predetermined position of the mask 30 at the second scan. The figure depicts the right half of the mask 30 at the first scan, and only part, near the left end, of the mask 30 at the second scan. A line segment in the scanning direction, joining the right end of the mask 30 at the first scan and the left end of the mask 30 at the second end is a boundary between the scans (a mask joint boundary).

The mask 30 includes opening blocks 50 arranged side by side in a row direction perpendicular to the scanning direction. Each of the opening blocks 50 includes openings 51 aligned in a column direction parallel to the scanning direction. Each opening block is a division on the mask 30 that allows opening 51 to be aligned in the column direction. In FIG. 5, the portion surrounded by a dashed line is an opening block 50 that includes 10 openings 51. For example, it is possible to give W≈x and L≈Mxy for the sake of convenience, where “W” is a dimension of the mask 30 in the direction parallel to the scanning direction, “L” is a dimension thereof in the direction perpendicular to the scanning direction, “M” is the number of the opening blocks 50, “x” is a dimension of each opening block 50 in the column direction, and “y” is a dimension of the opening blocks 50 in the row direction.

In the example of FIG. 5, twenty-one opening blocks 50 in Columns M1, M2, . . . , M21 are arranged side by side from the center to one end of the mask 30. Note that the number of the opening blocks 50 is not limited to the example of the example of FIG. 5.

In the present specification, an opening block 50 including openings 51 means not only a state in which the openings 51 aligned at regular intervals occupy from one end to the other in the column direction of the opening block 50, but also a state in which part with openings 51 in the column direction not occupied (i.e., part where any openings 51 do not exist) exists. For example, in the case of the opening block 50 in Column M1, any openings 51 do not exist in both sides in the column direction.

Focusing on the opening block 50 in Column M4 and the opening block 50 in Column M5, the opening block 50 in Column M4 and the opening block 50 in Column M5 are adjacent two opening blocks. The position of the openings 51 of the opening block 50 in Column M5 is shifted in the scanning direction relative to the position of the openings 51 of the opening block 50 in Column M4. If the opening block 50 in Column M4 is the first opening block, the opening block 50 in Column M5 corresponds to the second opening block.

Specifically, the position of ten openings 51, in the column direction, of the opening block 50 in Column M5 (from the opening 51 at the end to a tenth opening 51 inclusive) is shifted in the scanning direction by a distance corresponding to a predetermined pitch of the openings 51 relative to the position of ten openings 51, in the column direction, of the opening block 50 in Column M4 (from the opening 51 at the end to a tenth opening 51 inclusive) (reference symbol “A1”).

The position of ten openings 51, in the column direction, of the opening block 50 in Column M13 is shifted in the scanning direction by a distance corresponding to three times the pitch of the openings 51 relative to the position of ten openings 51, in the column direction, of the opening block 50 in Column M12 (reference symbol “A3”). If the opening block 50 in Column M12 is the first opening block, the opening block 50 in Column M13 corresponds to the second opening block.

The position of ten openings 51, in the column direction, of the opening block 50 in Column M19 is shifted in the scanning direction by a distance corresponding to five times the pitch of the openings 51 relative to the position of ten openings 51, in the column direction, of the opening block 50 in Column M18 (reference symbol “A5”). If the opening block 50 in Column M18 is the first opening block, the opening block 50 in Column M19 corresponds to the second opening block.

Focusing on the opening block 50 in Column M8 and the opening block 50 in Column M9, the opening block 50 in Column M8 and the opening block 50 in Column M9 are adjacent two opening blocks. The position of the openings 51 of the opening block 50 in Column M9 is shifted in the direction opposite to the scanning direction by a distance corresponding to two times the pitch of the openings 51 relative to the position of the openings 51 of the opening block 50 in Column M8 (reference symbol “A2”). If the opening block 50 in Column M8 is the first opening block, the opening block 50 in Column M9 corresponds to the second opening block.

The position of ten openings 51, in the column direction, of the opening block 50 in Column M16 is shifted in the direction opposite to the scanning direction by a distance corresponding to four times the pitch of the openings 51 relative to the position of ten openings 51, in the column direction, of the opening block 50 in Column M15 (reference symbol “A4”). If the opening block 50 in Column M5 is the first opening block, the opening block 50 in Column M16 corresponds to the second opening block.

Note that of the opening blocks 50 arranged in the row direction, every adjacent two opening blocks may be configured so that their respective positions of the openings 51 are shifted relative to each other, or part of every adjacent two opening blocks of the opening blocks 50 arranged in the row direction may be configured so that their respective positions of the openings 51 are shifted relative to each other. In the example of FIG. 5, of opening blocks 50 in Columns M1 to M21 arranged in the row direction, each set of two opening blocks 50 in Columns M4 and M5, two opening blocks 50 in Columns M8 and M9, two opening blocks 50 in Columns M12 and M13, two opening blocks 50 in Columns M15 and M16, and two opening blocks 50 in Columns M18 and M19 is configured so that respective positions of the openings 51 of each set are shifted relative to each other. Note that although not illustrated, of respective sets of two opening blocks 50 in Columns M4 and M5, two opening blocks 50 in Columns M8 and M9, two opening blocks 50 in Columns M12 and M13, two opening blocks 50 in Columns M15 and M16, and two opening blocks 50 in Columns M18 and M19, the position of openings of one opening block of at least one set, and the position of openings of another opening block of the same set need to be shifted relative to each other in the direction parallel to the scanning direction.

Openings 51, to be shifted in position, of each of the first and second opening blocks may be all or part thereof. In the example of FIG. 5, all the openings 51 included in the first or second opening block are shifted in the direction parallel to the scanning direction.

The position of ten openings 51 of each of the opening blocks 50 in Columns M1 to M3 is not shifted in the direction parallel to the scanning direction relative to the position of ten opening 51 of the opening block 50 in Column M4 that is the first opening block. Each of the opening blocks 50 in Columns M1 to M3 corresponds to the fourth opening block.

The position of ten openings 51 of each of the opening blocks 50 in Columns M6 to M7 is not shifted in the direction parallel to the scanning direction relative to the position of ten opening 51 of the opening block 50 in Column M5 that is the second opening block, or the position of ten opening 51 of the opening block 50 in Column M8 that is the first opening block. Each of the opening blocks 50 in Columns M6 to M7 corresponds to the fourth opening block. Similarly, each of the opening blocks 50 in Columns M10 to M11, the opening block 50 in Column M17, and the opening blocks 50 in Columns M20 to M21 corresponds to the fourth opening block.

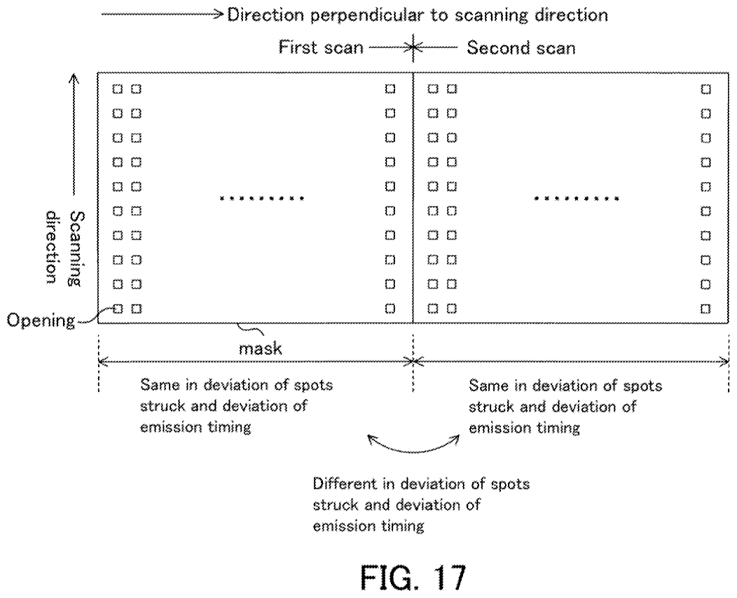

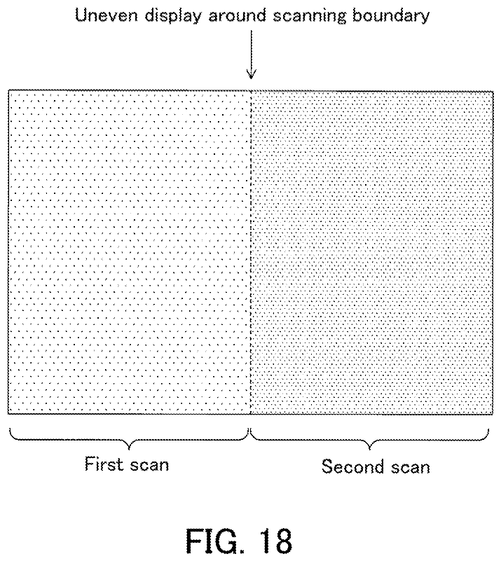

As illustrated in FIG. 5, the position of the openings 51 of each first opening block and the position of the openings 51 of a corresponding second opening block are shifted relative to each other in the direction parallel to the scanning direction. This configuration enables the arrangement of the openings 51 in the direction perpendicular to the scanning direction to be irregular, whereas such arrangement is constant in the conventional mask as illustrated in FIG. 17.

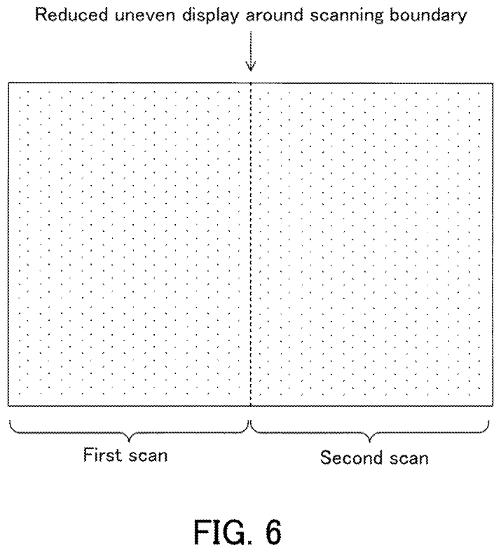

FIG. 6 is a schematic illustration depicting a state of a display area corresponding to spots struck by laser beams from the laser annealing device 100 according to the present embodiment. In FIG. 6, the left rectangle illustrates a display area corresponding to the spots struck at the first scan, and the right rectangle illustrates a display area corresponding to the spots struck at the second scan. As illustrated in FIG. 6, at the first scan, the spots struck in the direction perpendicular to the scanning direction disperse every timing of the laser beam emission. It is therefore possible to make a difference in the characteristics of a semiconductor layer in the direction perpendicular to the scanning direction, thereby deliberately generating uneven display. This makes it possible to make uneven display, around the boundary between the first and second scans (the mask joint boundary), less visible, thereby consequently reducing the uneven display at the mask joint boundary.

An arrangement example of the openings 51 of the mask 30 according to the present embodiment will next be described.

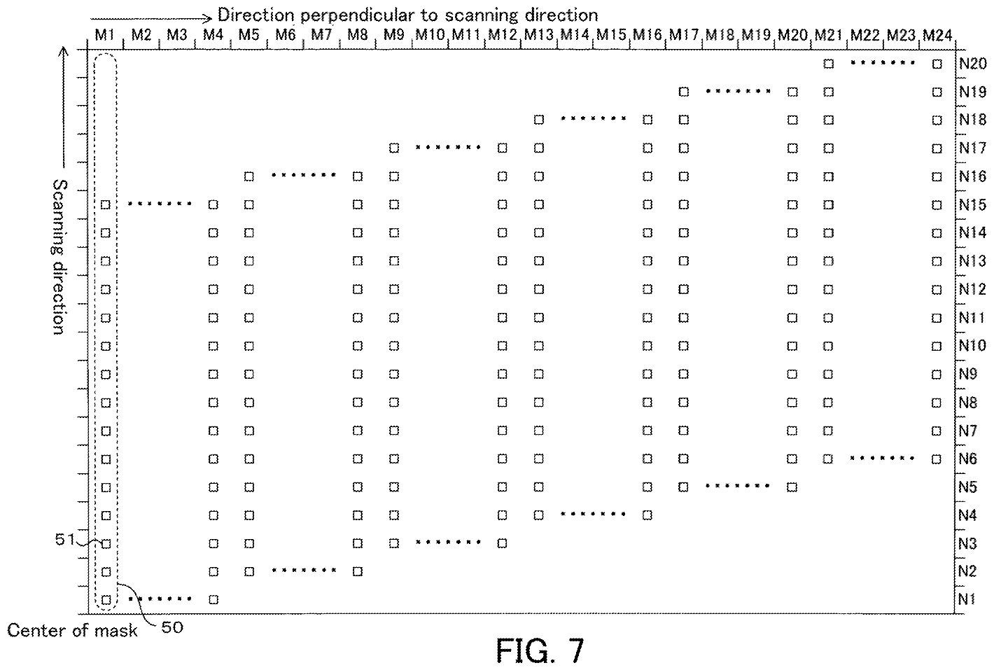

FIG. 7 is a schematic illustration depicting a first arrangement example of openings 51 in a mask 30 according to the present embodiment. For the sake of convenience, the mask 30 is divided at the center thereof in a direction perpendicular to a scanning direction, and part of the mask 30 from the center to one end (e.g., a right half) is illustrated. The half of the mask 30 will hereinafter be described. The mask 30 includes 24 opening blocks 50 in Columns M1 to M24 arranged in a row direction perpendicular to the scanning direction. Unillustrated 20 micro-lenses in Rows N1 to N20 are arranged side by side in the direction parallel to the scanning direction of the mask 30. The openings 51 of each opening block 50 are arranged so as to correspond to predetermined fifteen micro-lenses of corresponding twenty micro-lenses in Rows N1 to N20.

The position of fifteen openings 51 of the opening block 50 in Column M5 is shifted in the scanning direction by a distance corresponding to a predetermined pitch of the openings 51 relative to the position of fifteen openings 51 of the opening block 50 in Column M4. The position of openings 51 of the opening block 50 in Column M9 is shifted in the same way relative to the position of openings 51 of the opening block 50 in Column M8. The position of openings 51 of the opening block 50 in Column M13 is shifted in the same way relative to the position of openings 51 of the opening block 50 in Column M12. The position of openings 51 of the opening block 50 in Column M17 is shifted in the same way relative to the position of openings 51 of the opening block 50 in Column M16. The position of openings 51 of the opening block 50 in Column M21 is shifted in the same way relative to the position of openings 51 of the opening block 50 in Column M20.

The position of fifteen openings 51 of each opening block 50 in Columns M1 to M3 is not shifted in the direction parallel to the scanning direction. The position of fifteen openings 51 of each opening block 50 in Columns M6 and M7 is not shifted in the direction parallel to the scanning direction. The position of fifteen openings 51 of each opening block 50 in Columns M10 and M11 is not shifted in the direction parallel to the scanning direction. The position of fifteen openings 51 of each opening block 50 in Columns M14 and M15 is not shifted in the direction parallel to the scanning direction. The position of fifteen openings 51 of each opening block 50 in Columns M18 and M19 is not shifted in the direction parallel to the scanning direction. The position of fifteen openings 51 of each opening block 50 in Columns M22, M23, and M24 is not shifted in the direction parallel to the scanning direction. Each opening block 50 in Columns M1 to M3, M6, M7, M10, M11, M14, M15, M18, M19, M22, M23, and M24 corresponds to the fourth opening block.

The above-mentioned configuration enables the arrangement of openings 51 in a direction perpendicular to the scanning direction to shift in stages, thereby dispersing spots struck by collimated beams at the timing of laser beam emission. It is therefore possible to make a difference in the characteristics of a semiconductor layer within the area on the substrate scanned by one scan, thereby deliberately generating uneven display. This makes it possible to make uneven display around a mask joint boundary less visible, thereby consequently reducing the uneven display around the mask joint boundary.

A plurality of sets each of which includes the first opening block and the second opening block are arranged in the row direction. The example of FIG. 7 depicts five sets of Columns M4 and M5, Columns M8 and M9, Columns M12 and M13, Columns M16 and M17, and Columns M20 and M21. This enables the arrangement of openings 51 in the direction perpendicular to the scanning direction to shift at places in the row direction.

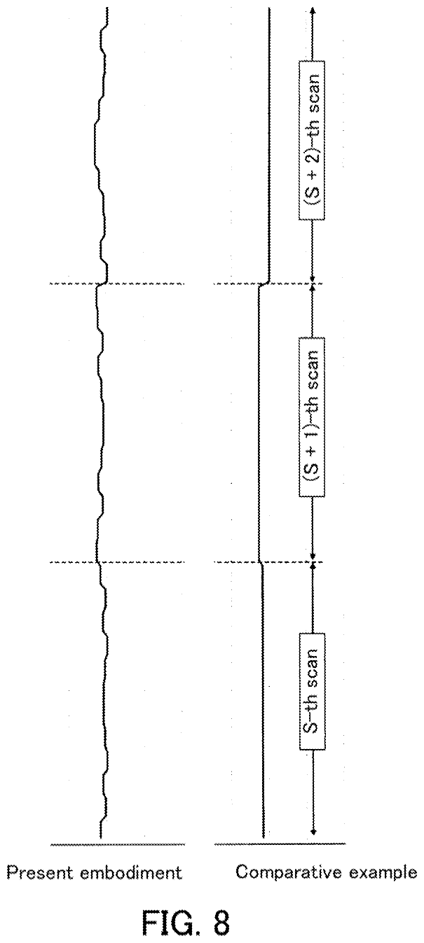

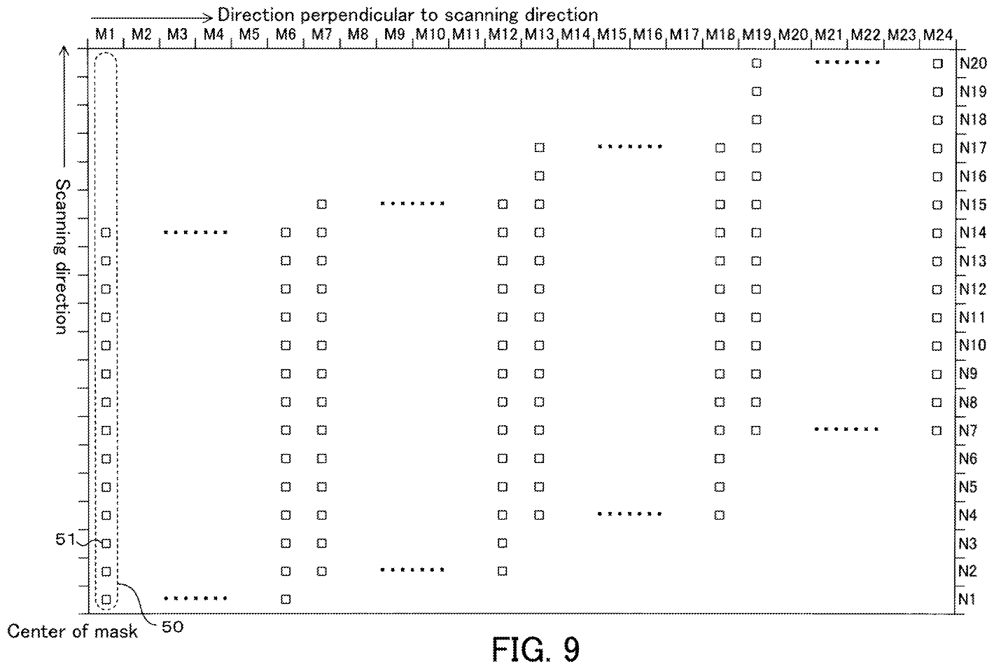

FIG. 8 is a schematic illustration depicting an example of the state in which uneven display in the display area containing mask joint boundaries brought about by a mask 30 according to the present embodiment is reduced. In FIG. 8, the transverse axis depicts the position in a direction perpendicular to a scanning direction, and the longitudinal axis depicts an evaluation value representing the degree of uneven display. FIG. 8 illustrates respective states when scan has been performed three times of S-th time, (S+1)-th time, and (S+2)-th time. The upper part of the figure illustrates the state derived from the mask 30 according to the present embodiment. For example, similar tendency is obtained in not only the first example illustrated in FIG. 7 but also later-mentioned examples illustrated in FIG. 9 and subsequent figures. Note that if the location of the display area is changed, the evaluation value differs from the value illustrated in FIG. 8, but has similar tendency. The lower part of the figure illustrates the state derived from a comparative example such as a conventional mask (e.g., illustrated in the example of FIG. 17).

In the case of the comparative example, although the evaluation values within the area on a substrate scanned by one scan are constant, the evaluation values around a mask joint boundary changes significantly. This causes noticeable uneven display around the mask joint boundary.

In contrast, in the case of the present embodiment, the evaluation values for each scan disperse within the area on the substrate scanned by one scan. Therefore, even when the evaluation values around the mask joint boundary changes, the dispersion of the evaluation values within the area on the substrate scanned by one scan makes a change in the evaluation values around the mask joint boundary less visible. It is consequently possible to reduce (suppress) uneven display around the mask joint boundary.

Relatively shifting respective positions of the openings 51 of adjacent opening blocks 50 by a predetermined distance in a direction parallel to the scanning direction enables stepwise shifting of openings 51 in the direction perpendicular to the scanning direction, thereby dispersing spots struck by collimated beams at the timing of laser beam emission. It is therefore possible to make a difference in the characteristics of a semiconductor layer within the area on the substrate scanned by one scan, thereby deliberately generating uneven display. This makes it possible to make uneven display around the mask joint boundary less visible, thereby consequently reducing the uneven display around the mask joint boundary.

One or more fourth opening blocks whose respective openings 51 are not shifted in terms of position in the direction parallel to the scanning direction are also arranged in a row direction, thereby causing the arrangement of openings 51 in the direction perpendicular to the scanning direction to be constant in an appropriate length. It is therefore possible to adjust the degree bringing about the dispersion in the spots struck at the timing of the laser beam emission.

FIG. 9 is a schematic illustration depicting a second arrangement example of openings 51 in a mask 30 according to the present embodiment. As illustrated in FIG. 9, the position of fourteen openings 51 of an opening block 50 in Column M7 is shifted in a scanning direction by a distance corresponding to a predetermined pitch of the openings 51 relative to the position of fourteen openings 51 of an opening block 50 in Column M6. The position of fourteen openings 51 of an opening block 50 in Column M13 is also shifted in the scanning direction by a distance corresponding to two times the pitch of the openings 51 relative to the position of fourteen openings 51 of an opening block 50 in Column M12. The position of fourteen openings 51 of an opening block 50 in Column M19 is also shifted in the scanning direction by a distance corresponding to three times the pitch of the openings 51 relative to the position of fourteen openings 51 of an opening block 50 in Column M18.

As stated above, of the above-described respective distances, namely predetermined distances (each of which is a shift dimension of the position of openings 50 in a direction parallel to the scanning direction), a predetermined distance with respect to first and second opening blocks at an end side of the mask 30 in a row direction can be made longer than a predetermined distance with respect to first and second opening blocks at a center side of the mask 30 in the row direction. That is, it is possible to make a position shift between respective openings 50 of the first and second opening blocks on the end side of the mask 30 larger than a position shift between respective openings 50 of the first and second opening blocks on the center side of the mask 30.

It is accordingly possible to gradually increase influence, at the above-described positions, of the deviation of the spots struck and the deviation of emission timing towards the end of the mask 30, thereby making uneven display around a mask joint boundary less visible.

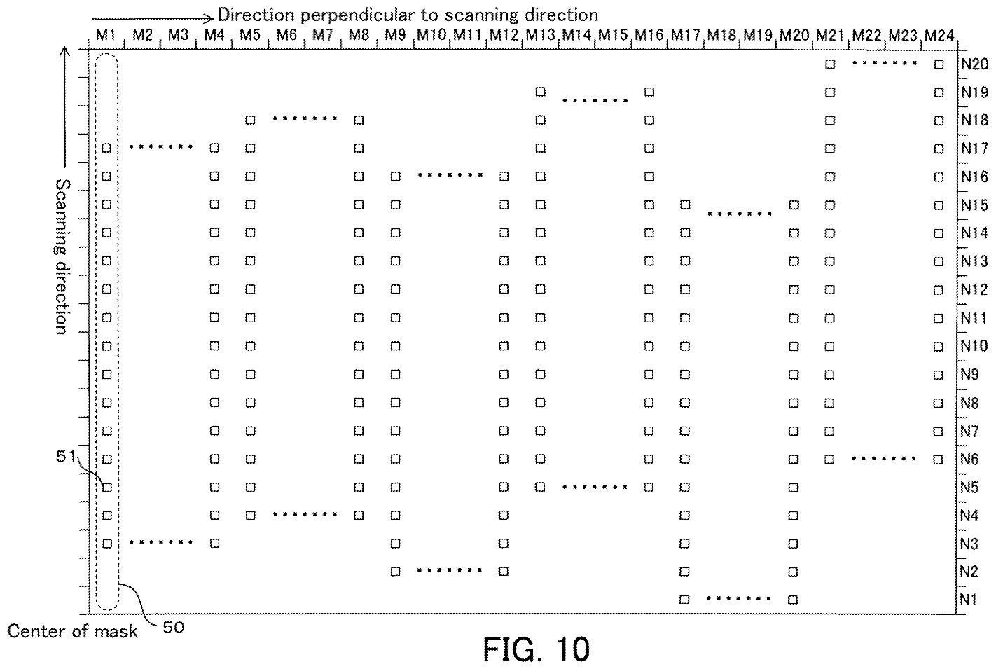

FIG. 10 is a schematic illustration depicting a third arrangement example of openings 51 in a mask 30 according to the present embodiment. As illustrated in FIG. 10, the position of fifteen openings 51 of an opening block 50 in Column M5 is shifted in a scanning direction by a distance corresponding to a predetermined pitch of the openings 51 relative to the position of fifteen openings 51 of an opening block 50 in Column M4. The position of fifteen openings 51 of an opening block 50 in Column M9 is also shifted in a direction opposite to the scanning direction by a distance corresponding to two times the pitch of the openings 51 relative to the position of fifteen openings 51 of an opening block 50 in Column M8. The position of fifteen openings 51 of an opening block 50 in Column M13 is also shifted in the scanning direction by a distance corresponding to three times the pitch of the openings 51 relative to the position of fifteen openings 51 of an opening block 50 in Column M12. The position of fifteen openings 51 of an opening block 50 in Column M17 is also shifted in the direction opposite to the scanning direction by a distance corresponding to four times the pitch of the openings 51 relative to the position of fifteen openings 51 of an opening block 50 in Column M16. The position of fifteen openings 51 of an opening block 50 in Column M21 is also shifted in the scanning direction by a distance corresponding to five times the pitch of the openings 51 relative to the position of fifteen openings 51 of an opening block 50 in Column M20.

As stated above, of each set of adjacent two first and second opening blocks, relative to the position of N-th (from first to n-th) openings 51 of a first opening block in each first set, the position of N-th (from first to n-th) openings 51 of a second opening block in each first set is shifted by integer times the pitch of openings 51 in the scanning direction. Here, in the example of FIG. 10, the first sets include three sets in Columns M4 and M5, Columns M12 and M13, and Columns M20 and M21.

Relative to the position of N-th (first to n-th) openings 51 of a first opening block in each second set, the position of N-th (first to n-th) openings 51 of a second opening block in each second set is shifted by integer times the pitch of openings 51 in the direction opposite to the scanning direction. Here, in the example of FIG. 10, the second sets include two sets of Columns M8 and M9, and Columns M16 and M17.

When openings 51 of each second opening block are shifted by an identical maximum distance, shifting the position of the openings 51 not only in the scanning direction but also in the direction different from the scanning direction by 180° as stated above makes it possible to more reduce the size (the dimension W in the direction parallel to the scanning direction) of the mask than shifting the position of the openings 51 only in the scanning direction.

Conversely, under the condition that respective mask sizes are the same as each other, the former makes it possible to more increase (lengthen) the shift distance of the openings 51. For example, the maximum shift distance of the openings 51 in the example of FIG. 9 is the distance equivalent to three times the pitch of the openings 51, whereas the example of FIG. 10 makes it possible to shift the openings 51 by the distance equivalent to five times the pitch of the openings 51.

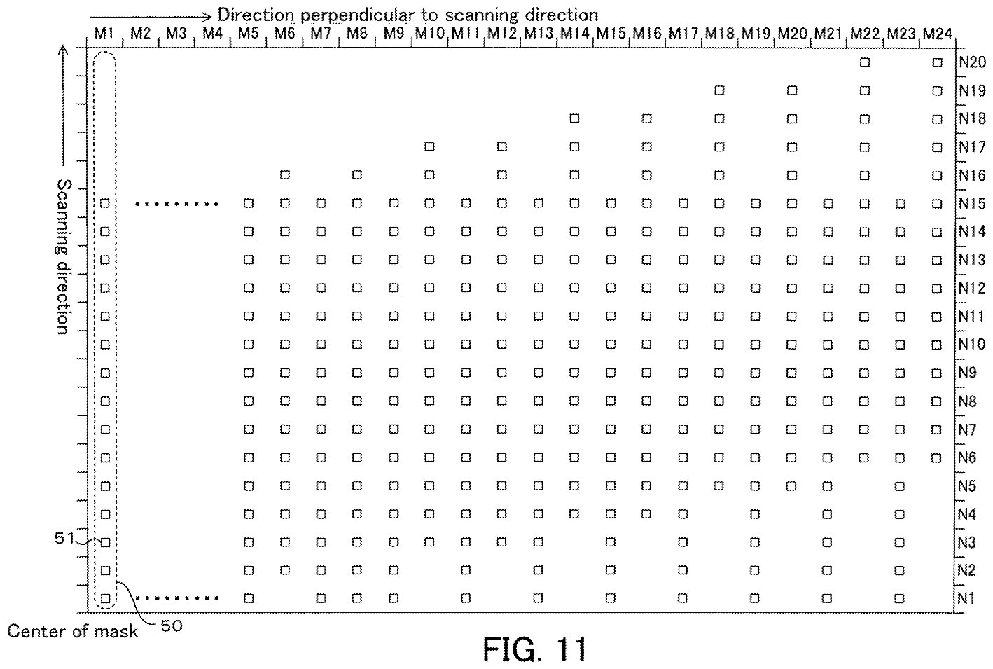

FIG. 11 is a schematic illustration depicting a fourth arrangement example of openings 51 in a mask 30 according to the present embodiment. As illustrated in FIG. 11, the position of fifteen openings 51 of an opening block 50 in Column M6 is shifted by a distance corresponding to a predetermined pitch of the openings 51 in a scanning direction relative to the position of fifteen openings 51 of an opening block 50 in Column M5. The position of fifteen openings 51 of an opening block 50 in Column M7 is also shifted by a distance corresponding to the pitch of the openings 51 in a direction opposite to the scanning direction relative to the position of the fifteen openings 51 of the opening block 50 in Column M6. The same applies to the opening blocks 50 in each of Column M7 and subsequent columns except the shift distance of the openings 51.

As stated above, the position of fifteen openings 51 of each second opening block (e.g., the opening block 50 in Column M6) is shifted by integer times the pitch of the openings 51 in the scanning direction relative to the position of fifteen openings 51 of a corresponding first opening block (e.g., the opening block 50 in Column M5). Relative to the position of fifteen openings 51 of each second opening block (e.g., the opening block 50 in Column M6), the position of fifteen openings 51 of a third opening block (e.g., the opening block 50 in Column M7) adjacent to the second opening block is shifted by integer times the pitch of the openings 51 in the direction opposite to the scanning direction.

That is, the configuration makes it possible to shift the position of openings 51 of an opening block 50 in each next column alternately in the scanning direction and the direction opposite to the scanning direction. As a result, the influence of the difference in the characteristics of a semiconductor layer for each column including opening blocks 50 is visually averaged, thereby making a boundary position of each set of adjacent opening blocks less visible.

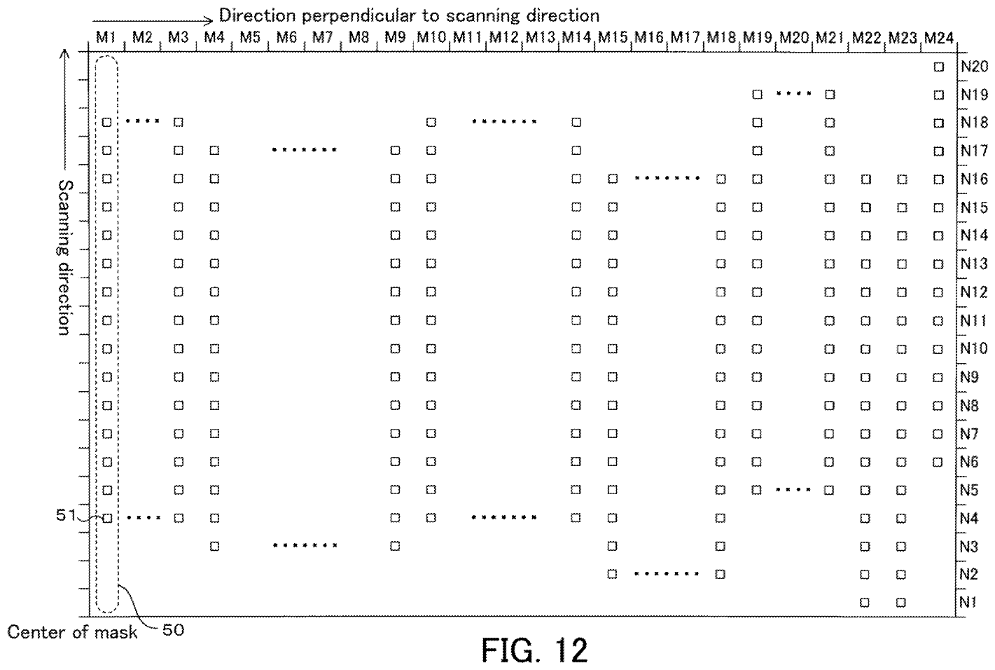

FIG. 12 is a schematic illustration depicting a fifth arrangement example of openings 51 in a mask 30 according to the present embodiment. As illustrated in FIG. 12, the position of fifteen openings 51 of each of four opening blocks 50 in Columns M5 to M8 is not shifted in a scanning direction relative to fifteen openings 51 of an opening block 50 in Column M4 or fifteen openings 51 of an opening block 50 in Column M9. The position of fifteen openings 51 of each of three opening blocks 50 in Columns M11 to M13 is not shifted in the scanning direction relative to fifteen openings 51 of an opening block 50 in Column M10 or fifteen openings 51 of an opening block 50 in Column M14. The position of fifteen openings 51 of each of two opening blocks 50 in Columns M16 and M17 is not shifted in the scanning direction relative to fifteen openings 51 of an opening block 50 in Column M15 or fifteen openings 51 of an opening block 50 in Column M18. The position of fifteen openings 51 of one opening block 50 in Columns M20 is not shifted in the scanning direction relative to fifteen openings 51 of an opening block 50 in Column M19 or fifteen openings 51 of an opening block 50 in Column M21. Each opening block 50 in Columns M5 to M8, Columns M11 to M13, Columns M16 and M17, and Column M20 corresponds to the fourth opening block.

As stated above, it is possible to reduce the number of fourth opening blocks, for each set of fourth opening blocks, arranged in a row direction from an center side to an end side of the mask 30. By reducing the number of fourth opening blocks, for each set of fourth opening blocks, arranged in the row direction, the degree of the arrangement of openings 51 in a direction perpendicular to the scanning direction being uniform is reduced. This corresponds to an increase in a shift frequency in the scanning direction of the openings 51 in the direction perpendicular to the scanning direction. This configuration makes it possible to gradually increase the influence, at the above-described positions, of the deviation of spots struck by collimated beams and the deviation of emission timing toward an end side of the mask 30, thereby making uneven display around a mask joint boundary less visible.

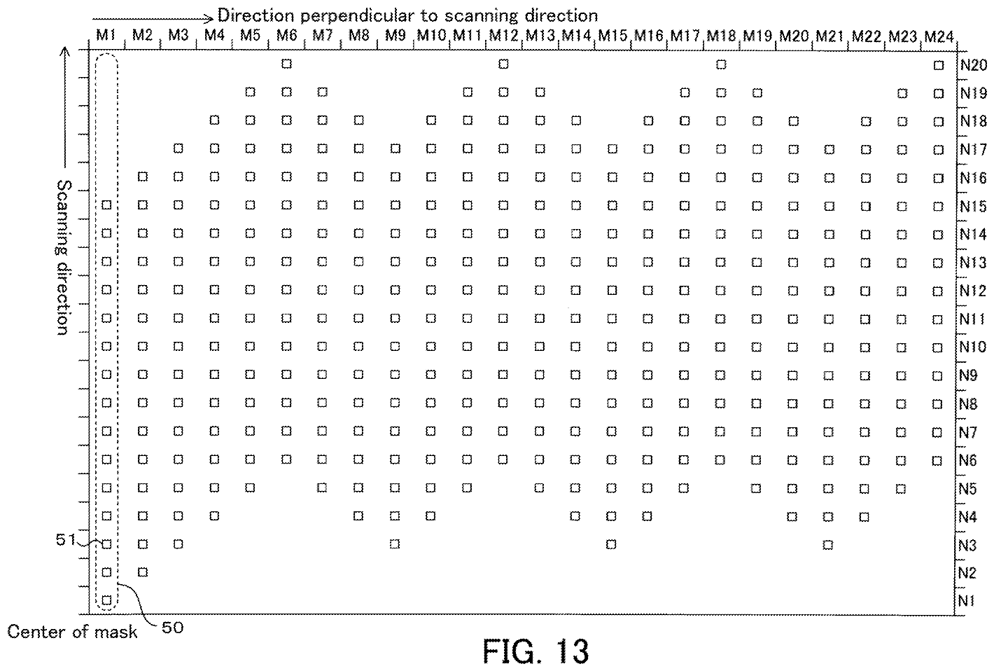

FIG. 13 is a schematic illustration depicting a sixth arrangement example of openings 51 of a mask 30 according to the present embodiment. As illustrated in FIG. 13, respective positions of fifteen openings 51 each, of opening blocks 50 in Columns M1 to M6 are shifted in a scanning direction so that the position of fifteen openings 51 of an opening block 50 on an end side of the mask 30 is nearer to an end of the mask 30 in the scanning direction than the position of fifteen openings 51 of an opening block 50 on a center side of the mask 30. Respective positions of fifteen openings 51 each, of opening blocks 50 in Columns M6 to M9 are shifted in a direction opposite to the scanning direction so that the position of fifteen openings 51 of an opening block 50 on the end side of the mask 30 is nearer to an end of the mask 30 in the direction opposite to the scanning direction than the position of fifteen openings 51 of an opening block 50 on the center side of the mask 30. Respective positions of fifteen openings 51 each, of opening blocks 50 in Columns M9 to M12 are shifted in the scanning direction so that the position of fifteen openings 51 of an opening block 50 on the end side of the mask 30 is nearer to the end of the mask 30 in the scanning direction than the position of fifteen openings 51 of an opening block 50 on the center side of the mask 30.

Respective positions of fifteen openings 51 each, of opening blocks 50 in Columns M12 to M15 are shifted in the direction opposite to the scanning direction so that the position of fifteen openings 51 of an opening block 50 on the end side of the mask 30 is nearer to the end of the mask 30 in the direction opposite to the scanning direction than the position of fifteen openings 51 of an opening block 50 on the center side of the mask. 30. Hereinafter, respective positions of fifteen opening blocks 51 each are repeatedly shifted in the scanning direction or the direction opposite to the scanning direction as the same way as the above-described configuration.

Note that the number of columns of opening blocks 50 whose respective openings 51 are stepwise shifted in the scanning direction, and the number of columns of opening blocks 50 whose respective openings 51 are stepwise shifted in the direction opposite to the scanning direction are not limited to that in the example of FIG. 13, but may be determined as appropriate. The number of columns of the former opening blocks 50 and the number of columns of the latter opening blocks 50 may also be the same as or different from each other.

As stated above, one or more first sets of first and second opening blocks each (in the example of FIG. 13, the opening blocks 50 in Columns M1 to M6), and one or more second sets of first and second opening blocks each (in the example of FIG. 13, the opening blocks 50 in Columns M6 to M9) are repeatedly arranged in a row direction.

That is, from the center side to the end side of the mask 30, one or more first sets of first and second opening blocks each, including openings 51 whose position is shifted in the scanning direction are arranged, while one or more second sets of first and second opening blocks each, including openings 51 whose position is shifted in the direction opposite to the scanning direction are arranged. This arrangement is repeated periodically. It is accordingly possible to make the arrangement of fifteen openings 51 each in the direction perpendicular to the scanning direction irregular.

In the above-mentioned first to sixth examples, all openings 50 of each opening block 50 are shifted by an identical distance in a direction parallel to the scanning direction, but the present embodiment is not limited thereto. Only openings 51 of each part of adjacent opening blocks 50 may be shifted by an identical or different distance in the direction parallel to the scanning direction. Such a configuration example will hereinafter be described.

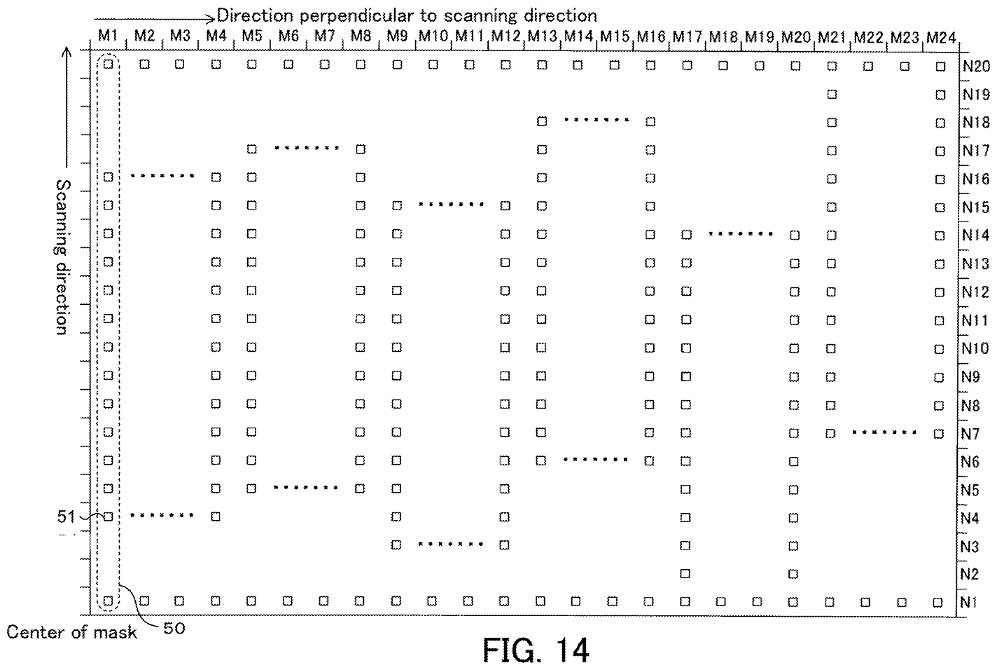

FIG. 14 is a schematic illustration depicting a seventh arrangement example of openings 51 of a mask 30 according to the present embodiment. As illustrated in FIG. 14, respective positions of two openings 51 each (two openings 51 each in Rows N and N20) at respective both ends of opening blocks 50 in Columns M1 to M24 are not shifted in a direction parallel to a scanning direction. The position of openings 51, within remaining rows except Columns N1 and N20, of the opening block 50 in Column M5 is shifted by a distance corresponding to a predetermined pitch of the openings 51 in the scanning direction relative to the position of openings 51, within remaining rows except Columns N1 and N20, of the opening block 50 in Column M4. The position of openings 51, within remaining rows except Columns N1 and N20, of the opening block 50 in Column M9 is shifted by a distance corresponding to two times the pitch of the openings 51 in a direction opposite to the scanning direction relative to the position of openings 51, within remaining rows except Columns N1 and N20, of the opening block 50 in Column M8. Other opening blocks 50 (in Columns M12 and M13, Columns M16 and M17, and Columns M20 and M21) are arranged in the same way except respective shift distances of their respective openings 51.

That is, of adjacent two opening blocks 50, the position of openings 51 of a first opening block (e.g., the opening block 50 in Column M4), and the position of openings 51 of a second opening block (e.g., the opening block 50 in Column M5) are shifted relative to each other in the direction parallel to the scanning direction.

Specifically, the position of voluntary N-th openings 51 including from an opening 51, at an end in a column direction, of a first opening block (e.g., an opening 51 in Row N1) to an n-th opening 51 inclusive, and the position of N-th openings 51 from an opening 51, at the end in the column direction, of a second opening block (e.g., an opening 51 in Row N1) to an n-th opening 51 inclusive are shifted relative to each other in the direction parallel to the scanning direction. The number of openings 51 shifted (N-th openings 51) may be one or more, and the opening 51 shifted may be part or all of openings 51 aligned in a column direction. In the example of FIG. 14, each of openings 51 within remaining rows except Row N1 and N20 corresponds to the openings 51 shifted (N-th openings 51). The direction parallel to the scanning direction includes not only the scanning direction but also the direction opposite to the scanning direction (a direction different from the scanning direction by 180°).

The above-mentioned configuration makes it possible to make arrangement of certain openings 51 each in the direction perpendicular to the scanning direction irregular and disperse spots struck by collimated beams at timing of laser beam emission. It is also possible to make a difference in the characteristics of a semiconductor layer within the area on a substrate scanned by one scan, thereby deliberately generating uneven display. It is therefore possible to make uneven display around a mask joint boundary less visible, thereby consequently reducing the uneven display around the mask joint boundary.

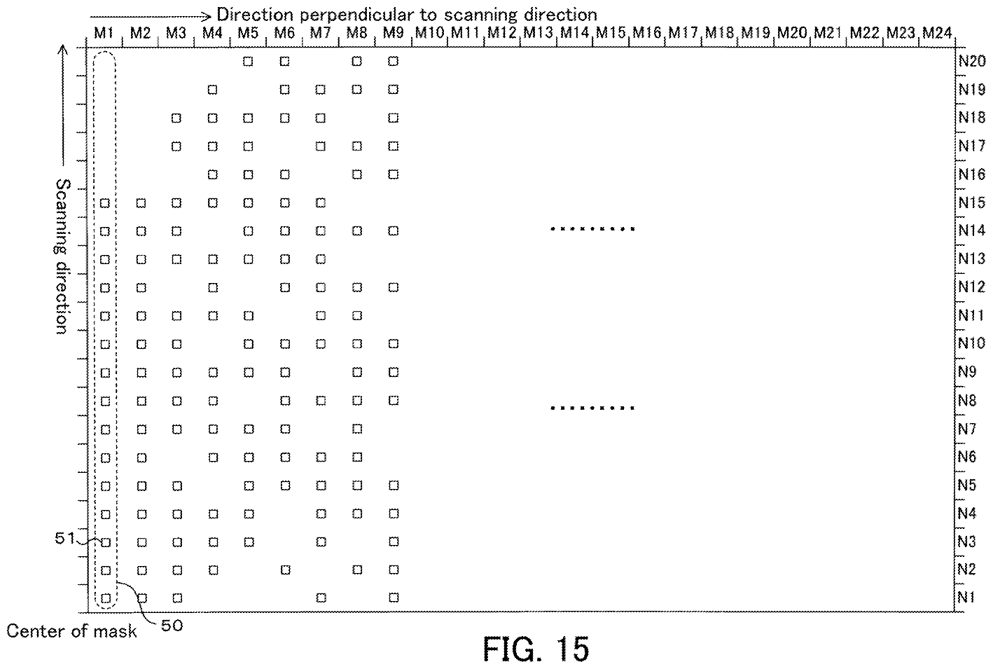

FIG. 15 is a schematic illustration depicting an eighth arrangement example of openings 51 of a mask 30 according to the present embodiment. As illustrated in FIG. 15, one or more parts of openings 51 of an opening block 50 in Column M3 is shifted in a direction parallel to a scanning direction relative to one or more parts of openings 51 of an opening block 50 in Column M2 so that respective positions of the one or more parts in Column M3 are different from respective positions of the one or more parts in Column M2. For example, the position of openings 51, from Rows N1 to N5, of the opening block 50 in Column M3 is not shifted in the direction parallel to the scanning direction relative to the position of openings 51, from Rows N1 to N5, of the opening block 50 in Column M2. The position of openings 51, from Rows N7 to Nil, of the opening block 50 in Column M3 is shifted by a distance corresponding to a predetermined pitch of the openings 51 in the direction parallel to the scanning direction relative to the position of openings 51, from Rows N6 to N10, of the opening block 50 in Column M2. The position of openings 51, from Rows N13 to N15, of the opening block 50 in Column M3 is shifted by a distance corresponding to two times the pitch of the openings 51 in the direction parallel to the scanning direction relative to the position of openings 51, from Rows N1 to N13, of the opening block 50 in Column M2. The position of openings 51, in Rows N17 and N18, of the opening block 50 in Column M3 is shifted by a distance corresponding to three times the pitch of the openings 51 in the direction parallel to the scanning direction relative to the position of openings 51, in Rows N14 and N15, of the opening block 50 in Column M2.

In the example of FIG. 15, of openings 51 of each opening block 50 in Columns M2 and M3, voluntary N-th openings 51 whose position is shifted relative to each other are 6th to 15th openings 51 in each column. Note that opening blocks 50 in other columns are also arranged in the same way, and description thereof is omitted.

The configuration as illustrated in the example of FIG. 15 makes it possible to make arrangement of openings 51 in the direction perpendicular to the scanning direction irregular and disperse spots struck by collimated beams at timing of laser beam emission. It is also possible to make a difference in the characteristics of a semiconductor layer within the area on a substrate scanned by one scan, thereby deliberately generating uneven display. It is therefore possible to make uneven display around a mask joint boundary less visible, thereby consequently reducing the uneven display around the mask joint boundary.

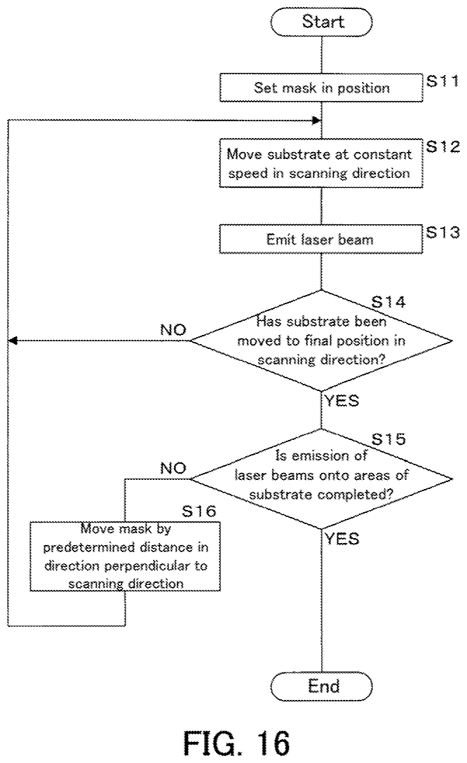

A laser annealing method using the laser annealing device 100 according to the present embodiment will next be described. FIG. 16 is a flow chart depicting an example of the laser annealing method using the laser annealing device 100 according to the present embodiment. For the sake of simplicity, the laser annealing device 100 is hereinafter referred to as a device 100. The device 100 sets the mask 30 in position (S1), and then moves the substrate 10 at a constant speed in the scanning direction (S12). The laser light source 70 emits a laser beam at time intervals-whenever spots to be struck by collimated beams on the substrate 10 reach respective positions corresponding to openings 51 of the mask 30 (S13).

The device 100 determines whether or not the substrate 10 has been moved to a final position in the scanning direction (S14). If the substrate 10 is not moved to the final position (NO at S14), the device 100 repeats processing of step S12 and subsequent steps. If the substrate 10 has been moved to the final position in the scanning direction (YES at S14), the device 100 determines whether or not laser beam emission to predetermined areas on the substrate 10 has been completed (S15).

If the laser beam emission to the predetermined areas on the substrate 10 has not been completed (NO at S15), the device 100 moves the mask 30 by a predetermined distance (a dimension L of the mask 30 in a transverse direction thereof) in the direction perpendicular to the scanning direction (S16). The device 100 then repeats processing of step S12 and subsequent steps. Note that in processing of step S16, the device 100 may move the substrate 10 in place of the mask 30. If the laser beam emission to the predetermined areas on the substrate 10 has been completed (YES at S15), the device 100 ends the process.

Note that in the configuration of the example of FIG. 16, the substrate 10 is moved (carried) in the scanning direction, but the present embodiment is not limited thereto. The mask 30 (may include an optical system 60) may be moved in the scanning direction with the substrate 10 fixed.

The present embodiment makes it possible to disperse spots struck by the collimated beams at timing of laser beam emission, and make a difference in the characteristics of a semiconductor layer within the area on the substrate scanned by one scan, thereby deliberately generating uneven display. It is therefore possible to make uneven display around the mask joint boundary less visible, thereby consequently reducing the uneven display around the mask joint boundary.

In particular, increasing the shift of the position of openings in the direction parallel to the scanning direction from the center side to an end side of the mask enables joining while dispersing the characteristics of a semiconductor layer between an area corresponding to the center of the mask and the boundary between the masks. That is, it is possible to expand an area in which the characteristic deviation within an allowable range occurs, and reduce uneven display around the mask joint boundary, in other words make unevenness caused by misalignment at a single place less visible.

In the present embodiment, the number of columns of opening blocks arranged in one mask and the number of openings in each opening block are not limited to those in the illustrated examples, but may be changed as appropriate.

In the above-mentioned embodiment, each opening 51 is rectangular in shape, but not limited to being rectangular. The shape may be, for example oval. Each rectangular opening 51 may have circular or rectangular cuts in four corners thereof. It is accordingly possible to slightly increase light quantity of laser beams near the four corners of each opening 51 to make spots struck by laser beams rectangular.

The present embodiment is applicable to not only a TFT with a silicon semiconductor but also a TFT with an oxide semiconductor.

A laser annealing device according to the present embodiment includes a mask including opening blocks arranged side by side in a row direction perpendicular to a scanning direction. Each of the opening blocks includes openings aligned in a column direction parallel to the scanning direction. The laser annealing device performs a process of moving at least one of the mask and a substrate in a direction parallel to the scanning direction, and emitting a laser beam to predetermined areas on the substrate through the openings whenever at least one of the mask and the substrate is moved to a predetermined position in a direction perpendicular to the scanning direction. The opening blocks include at least one set of adjacent two opening blocks. A position of an opening of a first opening block that is one opening block of the set, and a position of an opening of a second opening block that is the other opening block of the set are shifted relative to each other in the direction parallel to the scanning direction.

A laser annealing method according to the present embodiment is a laser annealing method using the laser annealing device according to the present embodiment. The laser annealing method includes moving, by the laser annealing device, at least one of the substrate and the mask in the direction parallel to the scanning direction to emit the laser beam on the substrate through the openings. The moving at least one of the substrate and the mask is performed whenever at least one of the mask and the substrate is moved to the predetermined position in the direction perpendicular to the scanning direction.

A mask according to the present embodiment is a mask including opening blocks arranged side by side in a row direction perpendicular to a scanning direction. Each of the opening blocks includes openings aligned in a column direction parallel to the scanning direction. The opening blocks include at least one set of adjacent two opening blocks. A position of an opening of a first opening block that is one opening block of the set, and a position of an opening of a second opening block that is the other opening block of the set are shifted relative to each other in the direction parallel to the scanning direction.

The mask includes the opening blocks, each of which includes the openings aligned in the column direction parallel to the scanning direction, arranged side by side in the row direction perpendicular to the scanning direction. For example, it is possible to give W=x and L z Mxy for the sake of convenience, where “W” is the dimension of the mask in the direction parallel to the scanning direction, “L” is the dimension of the mask in the direction perpendicular to the scanning direction, “M” is the number of the openings, “x” is the dimension of each opening block in the column direction, and “y” is the dimension of each opening block in the row direction. Examples of each opening block including openings include an opening block including openings that are aligned at regular intervals and occupy from an end to another end of the opening block in the column direction, and an opening block including part that is not occupied by openings in the column direction (i.e., part where any openings 51 do not exist).

In the above-described at least one set of adjacent two opening blocks, the position of the openings of the first opening block that is one opening block of the set, and the position of the openings of the second opening block that is the other opening block of the set are shifted relative to each other in the direction parallel to the scanning direction. The adjacent two opening blocks may include every adjacent two opening blocks of opening blocks arranged in the row direction, or include adjacent two opening blocks that are part of the opening blocks arranged in the row direction. Openings relatively shifted in each of the first and second opening blocks may be all or part of the openings included in the opening block in question.

This configuration makes it possible to make arrangement of openings in the direction perpendicular to the scanning direction irregular (although conventionally it was uniform) because the position of the openings of the first opening block and the position of the openings of the second opening block are shifted relative to each other in the direction parallel to the scanning direction. This makes it possible to disperse spots struck by beams at timing of laser beam emission, and make a difference in the characteristics of a semiconductor layer within the area on the substrate scanned by one scan, thereby deliberately generating uneven display. It is therefore possible to make uneven display around the mask joint boundary less visible, thereby consequently reducing the uneven display around the mask joint boundary.

In the laser annealing device according to the present embodiment, the position of N-th opening, from one end side, of the openings of the second opening block that are aligned in the column direction is shifted by a predetermined distance in the direction parallel to the scanning direction relative to at least the position of N-th opening, from one end side, of the openings of the first opening block that are aligned in the column direction. Here, the N-th indicates from first to predetermined ordinal. The predetermined ordinal corresponds to an integer not greater than a total number of the openings included in each of the opening blocks

The position of the N-th opening, from the one end side, of the openings of the second opening block that are aligned in the column direction is shifted by the predetermined distance in the direction parallel to the scanning direction relative to at least the position of the N-th opening, from the one end side, of the opening of the first opening block that are aligned in the column direction. The N-th indicates from first to predetermined ordinal. The predetermined ordinal corresponds to an integer not greater than a total number of the openings included in each of the opening blocks. The opening, on one end side in the column direction, of the opening block may be an opening on one end side, of openings on both end sides of the openings aligned in the column direction. Voluntary N-th openings may be all or part of openings aligned in the column direction. The direction parallel to the scanning direction includes not only the scanning direction but also the direction opposite to the scanning direction (the direction different from the scanning direction by 180°).

The above-mentioned configuration makes it possible to make arrangement of openings in the direction perpendicular to the scanning direction irregular, and disperse spots struck by beams at timing of laser beam emission to make a difference in the characteristics of a semiconductor layer within the area on the substrate scanned by one scan, thereby deliberately generating uneven display. It is therefore possible to make uneven display around the mask joint boundary less visible, thereby consequently reducing the uneven display around the mask joint boundary.

In the laser annealing device according to the present embodiment, the opening blocks of the mask include a third opening block that is adjacent to the second opening block and different from the first openings. The position of the N-th opening of the second opening block is shifted in the scanning direction relative to the position of the N-th opening of the first opening block. The position of N-th opening, from the one end side, of the openings of the third opening block that are aligned in the column direction is shifted in the direction opposite to the scanning direction relative to the position of the N-th opening of the second opening block.

The position of the N-th opening of the second opening block is shifted in the scanning direction relative to the position of the N-th opening of the first opening block. The position of the N-th opening of the third opening block that is adjacent to the second opening block and different from the first openings is shifted in the direction opposite to the scanning direction relative to the position of the N-th opening of the second opening block.

That is, the first opening block, the second opening block, and the third opening block are arranged in the row direction in that order. The first to n-th openings of the first opening block and the first to n-th openings of the second opening block are shifted relative to each other in the scanning direction. The first to n-th openings of the second opening block and the first to n-th openings of the third opening block are shifted relative to each other in the direction opposite to the scanning direction. The position of openings is shifted not only in the scanning direction but also in the direction different from the scanning direction by 180°, and it is thereby possible to make the mask's size (a dimension W in the direction parallel to the scanning direction) smaller than that in the case where the position of openings is shifted only in the scanning direction.

It is also possible to shift the position of openings alternately in the scanning direction and the direction opposite to the scanning direction every column of the opening blocks. Accordingly, the influence of the difference in the characteristics of a semiconductor layer for each column of the opening blocks is visually averaged, and therefore the boundary position of adjacent opening blocks is made less visible.

In the laser annealing device according to the present embodiment, the opening blocks of the mask include, as at least one set of the adjacent first and second opening blocks, a plurality of sets arranged in the row direction.

The plurality of sets each of which includes the first and second opening blocks are arranged in the row direction. It is accordingly possible to shift, in two or more places in the row direction, arrangement of openings in the direction perpendicular to the scanning direction.

In the laser annealing device according to the present embodiment, the plurality of sets includes two sets each of which includes the adjacent first and second opening blocks. Of the two sets: relative to the position of the N-th opening of the first opening block, on one side in the row direction, in a first set, the position of the N-th opening of the second opening block, on the other side in the row direction, in the first set is shifted in the scanning direction: and relative to the position of the N-th opening of the first opening block, on the one side in the row direction, in a second set, the position of the N-th opening of the second opening block, on the other side in the row direction, in the second set is shifted in a direction opposite to the scanning direction.

Of the two sets each of which includes the adjacent first and second opening blocks, the position of the N-th (first to n-th) openings of the second opening block, on the one side in the row direction, in the first set is shifted in the scanning direction relative to the position of the N-th (first to n-th) openings of the first opening block, on the other side in the row direction, in the first set.

The position of the N-th (first to n-th) openings of the second opening block, on the one side in the row direction, in the second set is shifted in the direction opposite to the scanning direction relative to the position of the N-th (first to n-th) openings of the first opening block, on the other side in the row direction, in the second set.

The above configuration makes it possible to shift, in two or more places in the row direction, arrangement of openings in the direction perpendicular to the scanning direction, thereby making the mask's size (a dimension W in the direction parallel to the scanning direction) smaller than that in the case where the position of the openings is shifted only in the scanning direction.

In the laser annealing device according to the present embodiment, the plurality of sets includes two sets each of which includes the adjacent first and second opening blocks. The mask further includes one or more fourth opening blocks arranged in the row direction between the two sets. The position of openings included in each of the one or more fourth opening blocks is not shifted in the direction parallel to the scanning direction relative to the position of openings of the first opening block or the position of openings of the second opening block.

One or more fourth opening blocks, each of which includes openings whose position is not shifted in the direction parallel to the scanning direction relative to the position of the openings of the first opening block or the position of the openings of the second opening block, are arranged in the row direction between the two sets each of which includes the adjacent first and second opening blocks. That is, the position of openings of each fourth opening block is not shifted relative to the position of the openings of the first opening block, or the position of the openings of the second opening block. The number of the fourth opening blocks arranged in the row direction may be determined as appropriate. Arranging one or more fourth opening blocks in the row direction enables adjustment of the degree of variation in spots struck by beams at the timing of laser beam emission because the arrangement of openings in the direction perpendicular to the scanning direction can be made constant by an appropriate distance.

In the laser annealing device according to the present embodiment, respective predetermined distances with respect to the plurality of sets increase from a set of the first and second opening blocks on a center side of the mask in the row direction to a set of the first and second opening blocks on an end side of the mask in the row direction.

The respective predetermined distances (a shift dimension of the position of the openings in the direction parallel to the scanning direction) increase from the set of the first and second opening blocks on the center side of the mask in the row direction to the set of the first and second opening blocks on the end side of the mask in the row direction. That is, relative position shift between the opening of the first opening block and the opening of the second opening block in each of the plurality of sets is made larger from the center side to the end side of the mask. This makes it possible to gradually increase the influence, at the respective positions, of the deviation of spots struck by beams and the deviation of emission timing toward the end of the mask, thereby making uneven display around the mask joint boundary less visible.

In the laser annealing device according to the present embodiment, the mask includes, as the one or more fourth opening blocks, a plurality of sets each of which includes the one or more fourth opening blocks, arranged in the row direction.

Respective numbers of the fourth opening blocks of the plurality of sets decrease from a set on a center side of the mask to a set on an end side of the mask.

The respective numbers of the fourth opening blocks of the plurality of sets arranged in the row direction decrease from the center side to the end side of the mask. Decreasing the respective numbers of the fourth opening blocks of the plurality of sets arranged in the row direction enables reducing the degree of uniform arrangement of openings in the direction perpendicular to the scanning direction. This corresponds to an increase in a frequency of shift in the scanning direction of openings in the direction perpendicular to the scanning direction. This makes it possible to gradually increase the influence, at the respective positions, of the deviation of spots struck by beams and the deviation of emission timing towards the end of the mask, thereby making uneven display around the mask joint boundary less visible.

In the laser annealing device according to the present embodiment, the mask includes, as the first set of the first and second opening blocks, and the second set of the first and second opening blocks, one or more first sets and one or more second sets, respectively. The one or more first sets and the one or more second sets are repeatedly arranged in the row direction.

The one or more first sets each of which includes the first and second opening blocks, and the one or more second sets each of which includes the first and second opening blocks are repeatedly arranged in the row direction. That is, from the center side to the end side of the mask, the one or more first sets in each of which the openings of one opening block is shifted in the scanning direction relative to the openings of the other opening block are arranged, and the one or more second sets in each of which the openings of one opening block is shifted in the direction opposite to the scanning direction relative to the openings of the other opening block are arranged. The arrangement is periodically repeated. This enables uneven arrangement of openings in the direction perpendicular to the scanning direction.

In the laser annealing device according to the present embodiment, the predetermined distance is a distance corresponding to integer times a pitch of the openings.

The predetermined distance is a distance corresponding to integer times the pitch of the openings.

For example, the position of a first opening (an opening on an end side) of the second opening block is shifted by a distance corresponding to integer times the pitch of the openings in the direction parallel to the scanning direction relative to a first opening (an opening on the end side) of the first opening block. The position of a second opening of the second opening block is shifted by a distance corresponding to integer times the pitch of the openings (e.g., a distance that is the same as position shift between both the first openings) in the direction parallel to the scanning direction relative to the position of a second opening of the first opening block. If the total number of openings included in each opening block is “n”, the same applies to the respective positions of the third to n-th openings.

The above-mentioned configuration enables stepwise shift of arrangement of openings in the direction perpendicular to the scanning direction to disperse spots struck by beams at timing of laser beam emission to make a difference in the characteristics of a semiconductor layer within the area on the substrate scanned by one scan, thereby deliberately generating uneven display. It is accordingly possible to make uneven display around the mask joint boundary less visible, thereby consequently reducing the uneven display around the mask joint boundary.

The configurations described in the above-mentioned embodiments can be combined with one another, and new technical features can be formed though the combinations.

### REFERENCE SIGNS LIST

10 Substrate
21 Micro-lens
30 Mask
50 Opening block
51 Opening

1. A laser annealing device, comprising
a mask including opening blocks arranged side by side in a row direction perpendicular to a scanning direction, each of the opening blocks including openings aligned in a column direction parallel to the scanning direction, the laser annealing device performing a process of moving at least one of the mask and a substrate in a direction parallel to the scanning direction, and emitting a laser beam to predetermined areas on the substrate through the openings whenever at least one of the mask and the substrate is moved to a predetermined position in a direction perpendicular to the scanning direction, wherein
the opening blocks include at least one set of adjacent two opening blocks, and a position of an opening of a first opening block that is one opening block of the set, and a position of an opening of a second opening block that is another opening block of the set are shifted relative to each other in the direction parallel to the scanning direction, a position of the first opening block and a position of the second opening block being shifted relative to each other in the direction parallel to the scanning direction so as not to exceed respective lengths of the first and second opening blocks.

2. The laser annealing device according to claim 1, wherein
relative to at least a position of N-th opening, from one end side, of the openings of the first opening block that are aligned in the column direction, a position of N-th opening, from the one end side, of the openings of the second opening block that are aligned in the column direction is shifted in the direction parallel to the scanning direction by a predetermined distance, and,
the N-th indicates from first to predetermined ordinal, the predetermined ordinal corresponding to an integer not greater than a total number of the openings included in each of the opening blocks.

3. The laser annealing device according to claim 2, wherein
the opening blocks of the mask include a third opening block that is adjacent to the second opening block and different from the first opening block, the third opening block including openings aligned in the column direction, and the position of the N-th opening of the second opening block is shifted in the scanning direction relative to the position of the N-th opening of the first opening block, and a position of an N-th opening, from the one end side, of the openings of the third opening block is shifted in a direction opposite to the scanning direction relative to the position of the N-th opening of the second opening block.

4. The laser annealing device according to claim 2, wherein
the opening blocks of the mask include, as at least one set of the adjacent first and second opening blocks, a plurality of sets arranged in the row direction.

5. The laser annealing device according to claim 4, wherein
the plurality of sets includes two sets each of which includes the adjacent first and second opening blocks, and of the two sets: relative to a position of the N-th opening of the first opening block, on one side in the row direction, in a first set, a position of the N-th opening of the second opening block, on a different side in the row direction, in the first set is shifted in the scanning direction; and
relative to a position of the N-th opening of the first opening block, on the one side in the row direction, in a second set, a position of the N-th opening of the second opening block, on the different side in the row direction, in the second set is shifted in a direction opposite to the scanning direction.

6. The laser annealing device according to claim 4, wherein
the plurality of sets includes two sets of the adjacent first and second opening blocks, and the mask further includes one or more fourth opening blocks arranged in the row direction between the two sets, a position of openings included in each of the one or more fourth opening blocks being not shifted in the direction parallel to the scanning direction relative to a position of openings of the first opening block or a position of openings of the second opening block.

7. The laser annealing device according to claim 4, wherein
respective predetermined distances with respect to the plurality of sets increase from a set of the first and second opening blocks on a center side of the mask in the row direction to a set of the first and second opening blocks on an end side of the mask in the row direction.

8. The laser annealing device according to claim 2, wherein
the predetermined distance is a distance corresponding to integer times a pitch of the openings.

9. The laser annealing device according to claim 6, wherein
the mask includes, as the one or more fourth opening blocks, a plurality of sets each of which includes the one or more fourth opening blocks, arranged in the row direction, and respective numbers of the fourth opening blocks of the plurality of sets decrease from a center side to an end side of the mask.

10. The laser annealing device according to claim 5, wherein
the mask includes, as the first set of the first and second opening blocks and the second set of the first and second opening blocks, one or more first sets and one or more second sets, respectively, and the one or more first sets and the one or more second sets are repeatedly arranged in the row direction.

11. A laser annealing method using the laser annealing device according to claim 1, comprising
moving, by the laser annealing device, at least one of the substrate and the mask in the direction parallel to the scanning direction to emit the laser beam on the substrate through the openings, wherein
the moving at least one of the substrate and the mask in the direction parallel to the scanning direction to emit the laser beam on the substrate through the openings is performed whenever at least one of the mask and the substrate is moved to the predetermined position in the direction perpendicular to the scanning direction.

12. A mask comprising
opening blocks arranged side by side in a row direction perpendicular to a scanning direction, each of the opening blocks including openings aligned in a column direction parallel to the scanning direction, wherein
the opening blocks include at least one set of adjacent two opening blocks, and a position of an opening of a first opening block that is one opening block of the set, and a position of an opening of a second opening block that is another opening block of the set are shifted relative to each other in the direction parallel to the scanning direction, a position of the first opening block and a position of the second opening block being shifted relative to each other in the direction parallel to the scanning direction so as not to exceed respective lengths of the first and second opening blocks.
